(19) United States
(12) Patent Application Publication
(10) Pub. No.: US 2026/0190308 A1
(43) Pub. Date: Jul. 2, 2026

(54) SHIELD TENT WITH EXCELLENT ELECTROMAGNETIC WAVE SHIELDING EFFECT

(71) Applicant: E-SONG EMC CO., LTD., Seoul (KR)

(72) Inventors: Jun-Gu SONG, Seoul (KR); Young-Du HEO, Seoul (KR); Sang-Ho CHO, Seoul (KR)

(21) Appl. No.: 19/207,983

(22) Filed: May 14, 2025

(30) Foreign Application Priority Data
Jan. 2, 2025 (KR) 10-2025-0000392

(51) Int. Cl. H05K 9/00

(52) U.S. Cl. CPC H05K 9/0003

(57) ABSTRACT

The present invention discloses a shield tent in which a polymer plate with a magnet or a metal attached is employed, or multiple curved polymer plates are arranged continuously. This provides easy opening and closing while offering excellent electromagnetic wave shielding effect. A shield tent according to the present invention comprises: a shield surface including an opening; and a door disposed on an outer surface of the shield surface, covering the opening. A first polymer plate, to which a magnet or a metal is attached, is disposed on an inner surface of the shield surface at an edge of the opening, and a second polymer plate, to which a magnet or a metal is attached, is disposed at an edge of the door.

### CROSS REFERENCE TO RELATED APPLICATION

This application claims priority under 35 U.S.C § 119 to Korean Patent Application No. 10-2025-0000392 filed on Jan. 2, 2025, in the Korean Intellectual Property Office, the entire contents of which are hereby incorporated by reference.

### TECHNICAL FIELD

The present invention relates to a shield tent having excellent electromagnetic wave shielding effect and allowing easy opening and closing by using polymer plates to which magnets or metals are attached.

Additionally, the present invention relates to a shield tent providing an excellent electromagnetic wave shielding effect by continuously arranging curved polymer plates to minimize the gap between the polymer plates.

### BACKGROUND

Recently, due to the rapid development of electronics and communication technologies, it has become technically feasible to use densely arranged unit circuits with various functions in a limited space.

Along with this, there is a problem of electromagnetic interference (EMI), in which mutual interference of electromagnetic waves (EMW, Electro Magnetic Wave) generated from each circuit among adjacent circuits causes device malfunctions.

In general, electromagnetic wave shielding means blocking the space between the external source of electromagnetic waves and the object to be protected with a shielding material, so that the electromagnetic waves do not penetrate into the interior, thereby protecting a human body, or a device that is vulnerable to electromagnetic waves. In this regard, the shielding effect refers to the extent to which the electromagnetic waves incident from outside are attenuated by reflection, absorption, or internal reflection in the medium through the shielding material.

When electromagnetic wave shielding is required, a common method is to protect electronic devices inside a structure, by using a structure such as a shield tent.

However, there has been a problem in which electromagnetic waves leak through the opening and closing portion of a door formed in the shield tent to allow user access. Conventional zippers (fasteners) have a gap between the zipper teeth through which electromagnetic waves may leak, thus limiting the improvement of shielding efficiency and also causing inconvenience due to long opening and closing times. In particular, the slider may detach when the corner portion is fastened.

In addition, in a conventional shield tent, a metal zipper is often used, requiring great force and time to open and close the entire door, with frequent malfunctions. When the door is installed in a double-door structure to improve shielding efficiency, at least twice as much time and labor are required. Velcro tape also poses difficulties in precisely attaching the upper and lower parts, and even if they do attach, the entire area must be pressed, causing inconvenience.

Therefore, there is a need for research on shield tents that provide excellent electromagnetic wave shielding performance while allowing easy opening and closing of the door.

### SUMMARY

It is an object of the present invention to provide a shield tent allowing easy opening and closing of the door while exhibiting excellent electromagnetic wave shielding effect.

It is another object of the present invention to provide a shield tent that may minimize damage to the shield surface.

A further object of the present invention is to provide a shield tent having a large shielding area and excellent attraction between polymer plates due to magnetic force.

The objects of the present invention are not limited to those stated above. Other objects and advantages of the present invention, not mentioned, may be understood from the following description and will become more apparent by way of the embodiments of the present invention. In addition, it will be readily appreciated that the objects and advantages of the present invention may be realized by the means, and combinations thereof, set forth in the appended claims.

A shield tent according to a first embodiment of the present invention comprises: a shield surface including an opening; and a door disposed on an outer surface of the shield surface and covering the opening; wherein a first polymer plate, to which a magnet or a metal is attached, is disposed on an inner surface of the shield surface at an edge of the opening, and a second polymer plate, to which a magnet or a metal is attached, is disposed at an edge of the door.

A shield tent according to a second embodiment of the present invention comprises: a shield surface including an opening; and a door disposed on an outer surface of the shield surface and covering the opening; wherein a plurality of first polymer plates is continuously arranged on an inner surface of the shield surface at an edge of the opening, and a plurality of second polymer plates is continuously arranged at an edge of the door; each first polymer plate comprises a magnet or a metal, and each second polymer plate comprises a magnet or a metal; on a side where one first polymer plate and another adjacent first polymer plate contact each other, a groove and a protrusion having the same shape as the groove face each other; and on a side where one second polymer plate and another adjacent second polymer plate contact each other, a groove and a protrusion having the same shape as the groove face each other as well.

According to the second embodiment, each the groove and protrusion may include a first surface and a second surface perpendicular to the first surface, or may include a curved surface.

According to the first or second embodiment, when the door is coupled to an edge of the opening on the outer surface of the shield surface, the rear surface of the first polymer plate may face the rear surface of the second polymer plate. Further, a cushioning sheet may be disposed at least at one location on the rear surface of the first polymer plate or the rear surface of the second polymer plate.

The cushioning sheet may comprise at least one resin selected from the group consisting of polyurethane-based resins, acrylic-based resins, ethylene propylene diene monomer (EPDM)-based resins, melamine-based resins, silicone-based resins, and fluorine-based resins.

According to the first or second embodiment, the magnet may include neodymium. The metal may include at least one of cobalt, iron, or nickel.

According to the first embodiment, each of the first polymer plate and the second polymer plate is accommodated in a pocket, and each pocket is fixed, in a sealed state, to the edge of the opening on the inner surface of the shield surface and to the edge of the door.

According to the second embodiment, a coupling member may be located on an upper portion of the first polymer plate, and a coupling member may be located on a lower portion of the second polymer plate. In this case, the coupling member of the first polymer plate may be in non-contact with the second polymer plate, and the coupling member of the second polymer plate may be in non-contact with the first polymer plate.

According to the first or second embodiment, the thickness of each the first polymer plate and the second polymer plate may range from 1 mm to 5 mm.

According to the first or second embodiment, the shield surface may include a stitch line where a first shield surface and a second shield surface overlap. A foam gasket may be disposed in the overlapping region on the inner surface of the shield surface so that the first shield surface and the second shield surface overlap on three continuous faces of the foam gasket. In that case, the stitch line of the overlapping first shield surface, second shield surface, and foam gasket may lie in the planar direction of the shield surface.

A shield tent according to the first or second embodiment of the present invention is easy to open and close, yet exhibits excellent electromagnetic wave shielding effect.

In particular, the shielding area is large, and there is excellent magnetic attraction between polymer plates; compared to a conventional shield tent using a zipper or Velcro tape, door opening and closing is easier and electromagnetic wave shielding efficiency may be further improved.

In a shield tent according to the second embodiment, curved polymer plates are continuously arranged to minimize the gap between the plates, thereby providing electromagnetic wave attenuation.

Furthermore, in the shield tent according to the second embodiment, damage to the shield surface may be minimized by controlling the position of the coupling members.

In addition to the effects described above, specific effects of the present invention will be described below while explaining specific details for carrying out the invention.

### BRIEF DESCRIPTION OF THE DRAWINGS

FIG. 1 illustrates the inner and outer surfaces, including an opening of a shield tent according to the first embodiment.

FIG. 2 is a plan view of a polymer plate 18, with a magnet 14 attached, according to the first embodiment.

FIG. 3 is a plan view of a polymer plate with a metal 16 attached, according to the first embodiment.

FIG. 4 shows a state in which a pocket 24 accommodating the polymer plate is attached to the shield tent according to the first embodiment.

FIG. 5 illustrates the inner and outer surfaces, including an opening of a shield tent, according to the second embodiment.

FIGS. 6 and 7 are plan views in which the first polymer plate 18, with either a magnet or a metal attached, is continuously arranged according to the second embodiment.

FIG. 8 is a plan view illustrating a state in which the first polymer plate 18 and the second polymer plate 22 face each other and are coupled, according to the second embodiment.

FIG. 9 is a photograph showing damage to the shield surface of the shield tent, where coupling members of the first polymer plate and the second polymer plate according to the second embodiment contact each other.

FIG. 10 is a cross-sectional view illustrating that a stitch line of a first shield surface 32, a second shield surface 34, and a foam gasket 40, according to the first or second embodiment, lies in the planar direction of the shield surface.

FIG. 11 illustrates a method for measuring shielding efficiency according to the first or second embodiment.

### DETAILED DESCRIPTION OF THE PREFERRED EMBODIMENTS

The above-described objects, features, and advantages will be described in detail below with reference to the accompanying drawings, allowing those skilled in the art to which the present invention pertains to readily implement the technical spirit of the present invention. In describing the present invention, detailed explanations of well-known technologies related to the present invention are omitted if it is determined that such explanations would unnecessarily obscure the subject matter of the present invention. Hereinafter, preferred embodiments of the present invention will be described in detail with reference to the accompanying drawings. In the drawings, the same reference numerals denote the same or similar elements.

Hereinafter, if an arbitrary configuration is the to be arranged at the “upper (or lower)” or “top (or bottom)” of a component, it may mean not only that the configuration is disposed in contact with the upper (or lower) surface of the component but also that another configuration may be interposed between the component and the arbitrary configuration disposed on (or under) that component.

In addition, if it is described that a certain component is “connected,” “coupled,” or “joined” to another component, it should be understood that the components may be directly connected or joined to each other, but another component may be “interposed” between them, or each component may be “connected,” “coupled,” or “joined” through another component.

Hereinafter, shield tents having excellent electromagnetic wave shielding effect according to some embodiments of the present invention will be described.

A shield tent according to the first or second embodiment of the present invention is easy to open and close, has a large shielding area, and offers excellent magnetic attraction between polymer plates. Accordingly, it provides outstanding electromagnetic wave shielding effect.

Such a shield tent may be used in laboratories, research facilities, or similar environments.

### First Embodiment

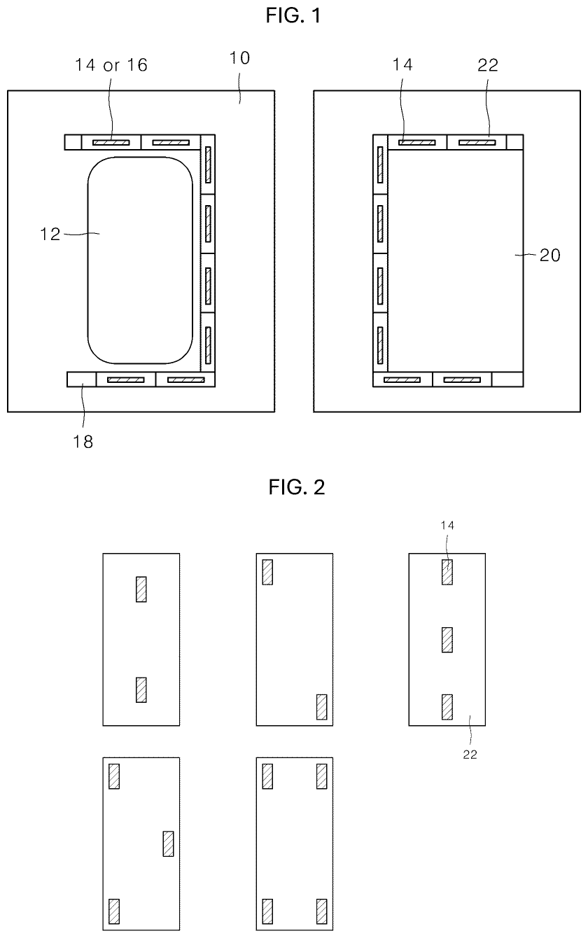

FIG. 1 illustrates the inner and outer surfaces, including an opening of a shield tent according to the first embodiment.

As shown in FIG. 1, the shield tent comprises the shield surface 10, which includes an opening, and a door 20 disposed on an outer surface of the shield surface to cover the opening. A first polymer plate to which a magnet or a metal is attached is disposed on an inner surface of the shield surface at the edge of the opening, and a second polymer plate to which a magnet or a metal is attached is disposed at the edge of the door.

The shield surface 10 includes an opening 12 that may be circular, rectangular, or another shape, and may be sized so that a device inside the shield tent may be moved outside through the opening or a user may easily enter and exit the shield tent.

The shield surface 10 may be formed of an electromagnetic wave shielding fabric by applying conductive particles to the fabric. The conductive particles may have an average particle diameter of up to 500 nm, and they may have a diameter ranging from 150 nm to 300 nm. The conductive particles may be formed in various structures, such as rod type, wire type, tube type, cable type, or belt type.

In addition, the conductive particles may be formed from a metal such as Ag or a conductive material such as CuI, ITO, SnO₂, or ZnO. A method of manufacturing the electromagnetic wave shielding fabric may involve mixing the conductive particles with ethanol to form an aqueous solution, then applying this solution to a high-density fabric to form a coating layer. Subsequently, a drying or heat-treatment process is performed so that the coating layer containing the conductive particles is fixed to the fabric. A transparent resin may further be coated on the electromagnetic wave shielding fabric in which the conductive particles are fixed, preventing the conductive particles from detaching.

The door 20 covers the opening 12 and may be a single-door structure rather than a double-door structure. In the present invention, since the edge of the opening is closely adhered by magnetic attraction, covering the opening with the door, a single door alone may provide a superior electromagnetic wave shielding effect.

On the inner surface of the shield surface 10 at the edge of the opening 12, a first polymer plate 18 having a magnet 14 or a metal 16 attached may be disposed.

In addition, at the edge of the door 20, a second polymer plate 22 with a magnet 14 or a metal (not shown) attached may be provided.

Using a first polymer plate and a second polymer plate, each having sufficient hardness, in the area to be shielded may enlarge the shielding area compared to using only magnets or metals. This approach also reduces gaps between the shield surface and the door, further improving the shielding efficiency of the shield tent.

Furthermore, the shape of the region to be shielded is retained by the polymer plate itself, allowing the door to more precisely cover the opening and enhancing the shielding effect by the area of the polymer plate.

Additionally, weight reduction may be achieved, maintaining durability at stitch lines of the shield tent while enhancing manufacturability.

Each of the first polymer plate 18 and the second polymer plate 22 may include, but is not limited to, a flat rectangular shape, a bent shape with an inclined surface, a semicircular shape, or a wedge shape with repeated rises and falls.

If each of the first polymer plate and the second polymer plate has a bent shape with an inclined surface or a wedge shape with repeated rises and falls, the compressive force between the plates increases, enhancing the shielding effect.

Each of the first and second polymer plates may include at least one of polypropylene resin, epoxy resin, acrylic resin, silicone resin, polyurethane resin, polyphenylene sulfide resin, polyvinyl chloride resin, or polycarbonate resin, and preferably may include a polycarbonate resin.

Each the first polymer plate and second polymer plate may include a high-density compressed foam that is obtained by foaming, then compressing, a composition containing the above resin for manufacturing each respective polymer plate.

The high-density compressed foam is produced by applying a high foaming ratio and a high compression ratio, and may include at least one of closed cells and open cells.

The magnet 14 may include neodymium. Including neodymium provides a strong magnetic force beneficial for electromagnetic wave shielding.

The metal 16 may include at least one of cobalt, iron, or nickel. By including at least one of cobalt, iron, or nickel, the metal offers reduction and weight favorable magnetic attraction to the magnet. A metal that includes at least one of cobalt, iron, or nickel may be used, for example, as an electro-galvanized (EGI) steel sheet, a nickel sheet, or a tinplate.

When comparing the sizes of the magnet and the metal, the metal area may be two to three times larger than that of the magnet. By forming the metal area two to three times larger than the magnet area, weight reduction and sufficient adherence to the first and second polymer plates may be secured.

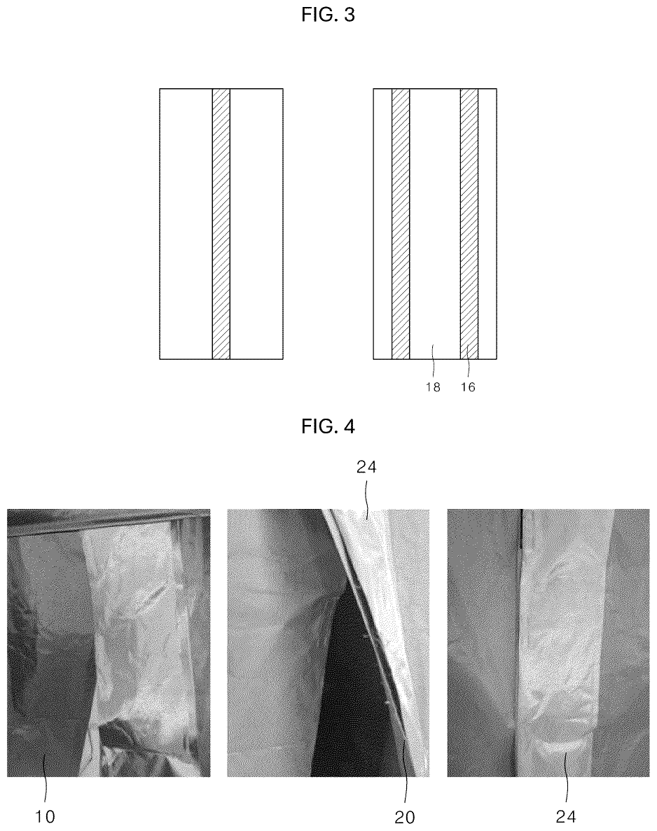

FIG. 2 is a plan view of a polymer plate with a magnet attached according to the first embodiment, and FIG. 3 is a plan view of a polymer plate with a metal attached according to the first embodiment.

As shown in FIGS. 2 and 3, the first polymer plate 18, having either a magnet 14 or a metal 16 attached, may have a plurality of magnets or a plurality of metals attached at intervals.

The second polymer plate 22 with magnet 14 attached may also have multiple magnets attached at intervals. Although FIG. 3 illustrates a magnet attached to the second polymer plate, this is not limiting. A metal may instead be attached to the second polymer plate.

In this case, the positions of the magnets or metals attached at intervals on the first polymer plate and the second polymer plate may correspond to each other.

In this manner, multiple magnets or metals may be attached at intervals on the first polymer plate 18, and multiple magnets or metals may be attached at intervals on the second polymer plate 22. By magnetic attraction, the first and second polymer plates may be easily brought into close contact with the shield surface and the door, further enhancing the shielding effect.

When the door is coupled to the edge of the opening 12 on the outer surface of the shield surface 10, the rear surface of the first polymer plate 18 may face the rear surface of the second polymer plate 22. This means that the rear surface of the first polymer plate, which has no magnet or metal attached, is adjacent to the rear surface of the second polymer plate, which also has no magnet or metal attached.

In other words, the flat rear surfaces come into close contact, allowing the door to cover the opening.

A cushioning sheet may be disposed at least at one location between the rear surface of the first polymer plate and the rear surface of the second polymer plate.

When the cushioning sheet is placed at least at one location between the rear surface of the first polymer plate and the rear surface of the second polymer plate, the adhesion therebetween is further enhanced. As a result, when the door is coupled to the edge of the opening, the electromagnetic wave shielding effect improves with no gaps.

From this perspective, the cushioning sheet may comprise at least one resin selected from the group consisting of polyurethane-based resins, acrylic-based resins, ethylene propylene diene monomer (EPDM)-based resins, melamine-based resins, silicone-based resins, and fluorine-based resins; preferably, it may include a polyurethane-based resin.

FIG. 4 shows a state in which a pocket accommodating the polymer plate, according to the first embodiment, is attached to the shield tent: (a) the inner surface of the shield surface, (b) the outer surface of the shield surface, and (c) a state in which the door is coupled to the shield surface.

As shown in FIG. 4, each of the first polymer plate with a magnet or metal attached and the second polymer plate with a magnet or metal attached may be contained in a pocket 24. Each pocket may then be fixed, in a sealed state, to the edge of the opening on the inner surface of the shield surface and to the edge of the door.

Like the shield surface, the pocket may be formed of an electromagnetic wave shielding fabric by applying conductive particles to the fabric.

Details thereof are the same as those described for the shield surface and will thus be omitted.

A magnet or metal may be attached to the first polymer plate by using a hot melt adhesive or hot melt tape, and likewise to the second polymer plate.

Additionally, Velcro tape may be used to secure the first and second polymer plates inside the pocket, and to secure the pocket to the shield surface and the door.

Meanwhile, instead of Velcro tape, a coupling member such as a button may be used by forming multiple holes in each of the first and second polymer plates, then placing the coupling member through those holes so as to fix the first and second polymer plates in the pocket.

To secure sufficient magnetic attraction and achieve weight reduction, the thickness of each the first and second polymer plate may range from 1 mm to 5 mm, and preferably from 2 mm to 4 mm.

If the door measures less than 1 m, for instance 200 mm×50 mm or 100 mm×50 mm, the shielding area may be reduced accordingly to secure the door area.

### Second Embodiment

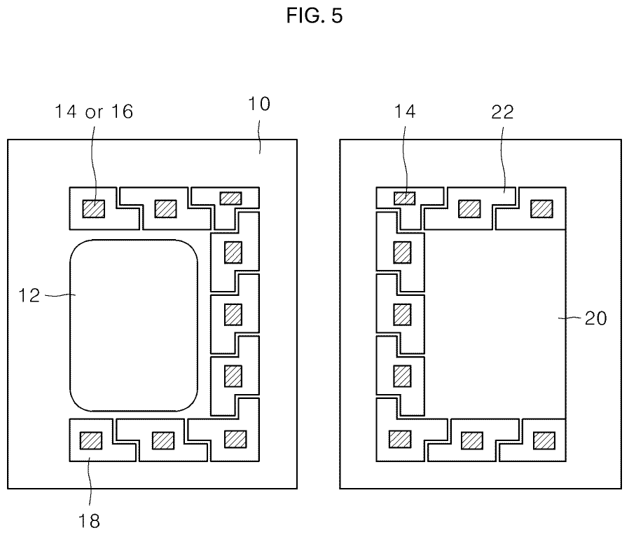

FIG. 5 illustrates the inner and outer surfaces, including an opening of a shield tent, according to the second embodiment.

As shown in FIG. 5, the shield tent according to the present invention includes the shield surface 10 having an opening, and a door 20 disposed on an outer surface of the shield surface to cover the opening.

A plurality of first polymer plates 18 is continuously arranged at the edge of the opening on the inner surface of the shield surface, and a plurality of second polymer plates 22 is continuously arranged at the edge of the door.

Each the first polymer plate 18 includes a magnet or a metal, and each the second polymer plate 22 includes a magnet or a metal.

On a side where one first polymer plate contacts another adjacent first polymer plate, a groove (A) and a protrusion (B), having the same shape as the groove, face each other. Likewise, on a side where one second polymer plate contacts another adjacent second polymer plate, a groove (A′) and a protrusion (B′), having the same shape as the groove, face each other.

The shield surface 10 includes an opening 12 of various shapes, such as circular or rectangular.

The shield tent may be large enough to allow a device inside it to be moved outside through the opening, or to allow a user to easily go in and out.

The shield surface 10 may be formed of an electromagnetic wave shielding fabric by applying conductive particles to the fabric.

The conductive particles may have an average particle diameter of up to 500 nm, and possibly in the range of 150 to 300 nm, but are not limited thereto.

The conductive particles may be formed in various structures, such as rod type, wire type, tube type, cable type, or belt type.

In addition, the conductive particles may be formed from a metal such as Ag or a conductive material such as CuI, ITO, SnO₂, or ZnO.

A method of manufacturing the electromagnetic wave shielding fabric may involve mixing the conductive particles in ethanol to form an aqueous solution, then applying that solution to a high-density fabric to form a coating layer.

Subsequently, a drying or heat-treatment process is performed so that the coating layer containing the conductive particles is fixed to the fabric. A transparent resin may further be coated on the electromagnetic wave shielding fabric in which the conductive particles are fixed, preventing the conductive particles from detaching.

The door 20 covers the opening 12 and may be a single-door structure rather than a double-door structure.

In the present invention, since the edge of the opening is closely adhered by magnetic attraction, covering the opening with the door, a single door alone may provide a superior electromagnetic wave shielding effect.

On the inner surface of the shield surface 10, at the edge of the opening 12, a plurality of first polymer plates 18 to which a magnet 14 or a metal 16 is attached may be continuously arranged.

Furthermore, at the edge of the door 20, a plurality of second polymer plates 22, each with a magnet 14 or a metal (not shown) attached, may be continuously arranged.

Using a first polymer plate and a second polymer plate, each having sufficient hardness, in the area to be shielded may enlarge the shielding area compared to using only magnets or metals. This approach also reduces gaps between the shield surface and the door, further improving the shielding efficiency of the shield tent.

Furthermore, the shape of the region to be shielded is retained by the polymer plate itself, allowing the door to more precisely cover the opening and enhancing the shielding effect by the area of the polymer plate.

Also, using polymer plates enables weight reduction, thus maintaining durability at the stitch lines of the shield tent while facilitating manufacturing.

In particular, in the present invention, at least two faces may be formed on the side where the polymer plates face one another.

Specifically, it is preferable that on the side where one first polymer plate contacts another adjacent first polymer plate, a groove and a protrusion having the same shape as the groove face each other.

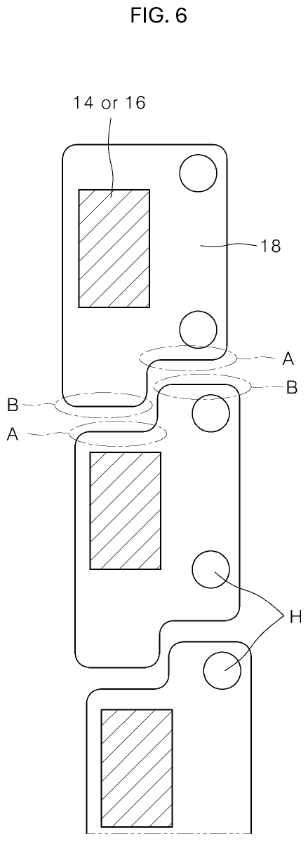

As illustrated in FIGS. 5 and 6, the side of one first polymer plate may include at least one groove and at least one protrusion. The side of another first polymer plate adjacent thereto may include a protrusion having the same shape as the groove and a groove having the same shape as the protrusion of the first polymer plate.

For example, if the right side of one first polymer plate includes a first groove and a first protrusion, then the left side of an adjacent first polymer plate may include a protrusion having the same shape as the first groove and a groove having the same shape as the first protrusion. When the groove and protrusion are arranged to match one another in this manner, any empty space between the first polymer plates is filled without gaps, allowing them to behave as if integrally formed.

Additionally, there is improved flexibility when opening and closing the door.

Hence, the space that opens or the gap between first polymer plates may be minimized, further improving the shielding performance.

Each the groove and protrusion may include a first surface and a second surface perpendicular to the first surface, or may include a curved surface.

For example, the shape of the groove and protrusion may be semicircular, triangular, rectangular, or any of various other shapes.

Preferably, as shown in FIG. 6, the groove and the protrusion may have a bent “L” shape that includes a first surface and a second surface perpendicular to the first surface.

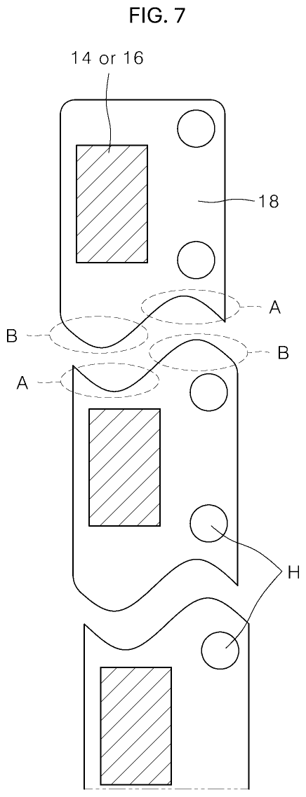

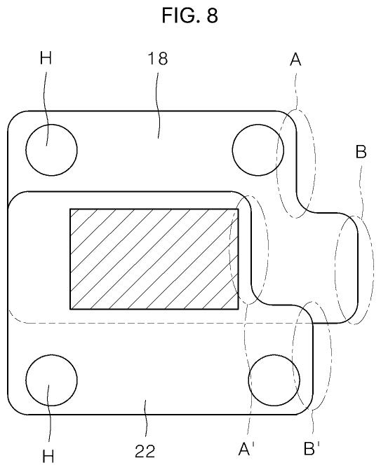

Alternatively, as shown in FIG. 7, the groove and the protrusion may have a wavy or curved shape, thereby improving flexibility when the door is opened or closed.

Moreover, in the present invention, on the side where one second polymer plate contacts another adjacent second polymer plate, it is preferable that a groove and a protrusion having the same shape as the groove face each other.

As with the first polymer plate, one second polymer plate may include at least one groove and at least one protrusion on its side. The side of another second polymer plate adjacent thereto may include a protrusion having the same shape as the groove, and a groove having the same shape as the protrusion of the second polymer plate.

For example, if the right side of one second polymer plate includes a first groove and a first protrusion, then the left side of an adjacent second polymer plate may include a protrusion having the same shape as the first groove and a groove having the same shape as the first protrusion. When the groove and protrusion are arranged to match one another in this manner, any empty space between the second polymer plates is filled without gaps, allowing them to behave as if integrally formed. Hence, the space that opens or the gap between second polymer plates may be minimized, further improving the shielding performance.

Since the types of the first and second polymer plates, magnet 14, and metal 16, according to the second embodiment, are the same as those described in the first embodiment, a detailed description thereof is omitted.

By including at least one of cobalt, iron, or nickel, the metal offers weight reduction and favorable magnetic attraction to the magnet. A metal that includes at least one of cobalt, iron, or nickel may be used, for example, as an electro-galvanized (EGI) steel sheet, a nickel sheet, or a tinplate.

When comparing the sizes of the magnet and the metal, the metal area may be two to three times larger than that of the magnet. By forming the metal area two to three times larger than the magnet area, weight reduction and sufficient adherence to the first and second polymer plates may be secured.

Referring again to FIG. 6, at least one magnet 14 is attached to the center of the first polymer plate 18.

Although FIG. 6 illustrates only one magnet 14 attached, this is not limiting. Multiple magnets may be attached at intervals depending on the required coupling strength of the door.

Instead of at least one magnet, at least one metal may be attached to the center of the first polymer plate.

At the center of the second polymer plate 22, at least one magnet 14 or at least one metal (not shown) may be attached. Depending on the coupling strength required for the door, multiple magnets may be attached at intervals, or multiple metals may be attached at intervals.

In this case, the positions of the magnets or metals attached to the first polymer plate and the second polymer plate may correspond to each other.

Thus, by attaching one magnet or metal to the center of the first polymer plate 18 and the second polymer plate 22, or attaching at least one magnet or metal at intervals, the first and second polymer plates may be easily brought into close contact with the shield surface and the door by magnetic attraction, further enhancing the shielding effect.

The magnet or metal may be attached to at least 50% of the area of the first polymer plate, although not limited thereto. A magnet may be attached to at least 50% of the area of the second polymer plate, but is also not limited thereto.

Each of the first and second polymer plates is contained in a pocket, and each pocket may be fixed in a sealed state to the edge of the opening on the inner surface of the shield surface and to the edge of the door.

A magnet or a metal may be attached to the first polymer plate, and likewise to the second polymer plate, by using a hot melt adhesive or hot melt tape.

In the present invention, a coupling member such as a button may be used by forming multiple holes in the upper portion of the first polymer plate and in the lower portion of the second polymer plate, then placing the coupling member through the holes to fix the first and second polymer plates to the shield surface.

FIG. 8 is a plan view illustrating a state in which the first polymer plate 18 and the second polymer plate 22 face each other and are coupled, according to the second embodiment.

In FIGS. 6 and 8, holes (H) are illustrated where a coupling member may be used.

The coupling member may be any one of a button, Velcro, or a screw coupling.

In addition to the button, the first polymer plate and the second polymer plate may be fixed by a Velcro attachment method, a screw coupling method, or the like.

As shown in FIG. 8, it is preferable that the coupling member of the first polymer plate remains in non-contact with the second polymer plate, and that the coupling member of the second polymer plate remains in non-contact with the first polymer plate.

By preventing the coupling members from contacting the opposite polymer plate, neither the magnet nor the metal is damaged, and the fabric of the shield surface is also preserved without damage.

Moreover, the first and second polymer plates may be coupled while facing each other in the same ratio, and the magnets or metals on the first polymer plate may be arranged in the same ratio as the magnets on the second polymer plate.

In the present invention, the thickness of each the first and second polymer plate may be adjusted according to the size of the door to which they are applied, and excellent shielding effects may be achieved regardless of their thickness.

For example, to secure sufficient magnetic attraction and reduce weight, each thickness of the first and second polymer plates may range from 1 mm to 5 mm, but is not limited thereto.

If the door measures less than 1 m, for instance 200 mm×50 mm or 100 mm×50 mm, the shielding area may be reduced accordingly to secure the door area.

When the door is coupled to the edge of the opening 12 on the outer surface of the shield surface 10, the rear surface of the first polymer plate 18 may face the rear surface of the second polymer plate 22. This means that the rear surface of the first polymer plate, which has no magnet or metal attached, is adjacent to the rear surface of the second polymer plate, which also has no magnet or metal attached. In other words, the flat rear surfaces come into close contact, allowing the door to cover the opening.

A cushioning sheet may be disposed at least at one location between the rear surface of the first polymer plate and the rear surface of the second polymer plate.

When the cushioning sheet is placed at least at one location between the rear surface of the first polymer plate and the rear surface of the second polymer plate, the adhesion therebetween is further enhanced. As a result, when the door is coupled to the edge of the opening, the electromagnetic wave shielding effect improves with no gaps.

From this perspective, the cushioning sheet may comprise at least one resin selected from the group consisting of polyurethane-based resins, acrylic-based resins, ethylene propylene diene monomer (EPDM)-based resins, melamine-based resins, silicone-based resins, and fluorine-based resins; preferably, it may include a polyurethane-based resin.

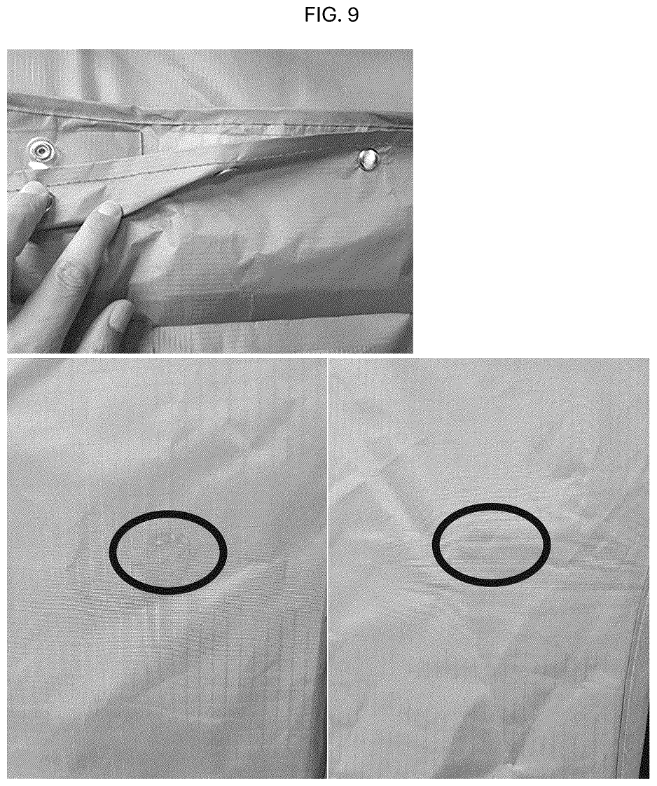

FIG. 9 is a photograph showing damage to the shield surface of the shield tent, where coupling members of the first polymer plate and the second polymer plate according to the second embodiment contact each other.

As shown in FIG. 9, the shield surface is damaged due to contact between the coupling members.

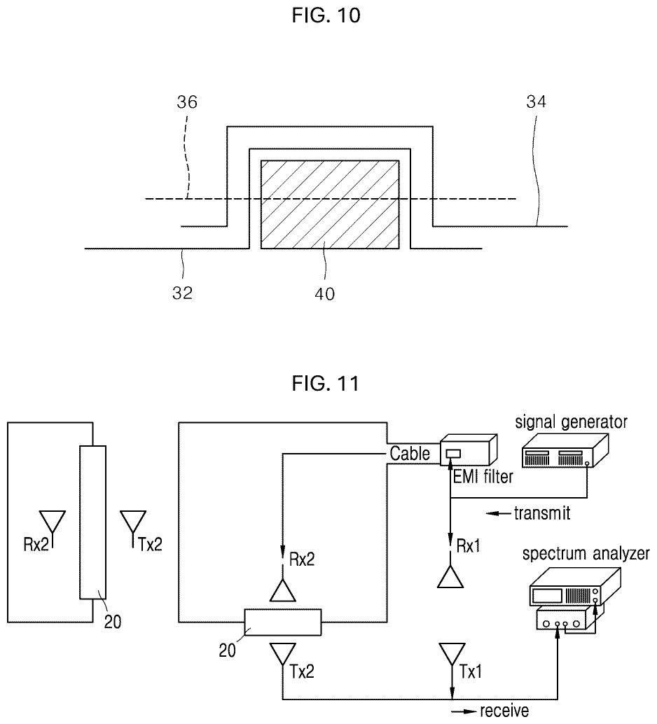

FIG. 10 is a cross-sectional view illustrating that the stitch line of the first shield surface, the second shield surface, and a foam gasket, according to the first or second embodiment, lies in the planar direction of the shield surface.

As shown in FIG. 10, the shield surface may include a stitch line 36 where a first shield surface 32 overlaps a second shield surface 34.

A foam gasket 40 is disposed in the overlapping region of the inner surface of the shield surface, such that the first shield surface 32 and the second shield surface 34 overlap on three continuous faces of the foam gasket 40. The stitch line 36 of the overlapping first shield surface 32, second shield surface 34, and foam gasket 40 may be in the planar direction of the shield surface 10. In other words, the stitch line 36 may lie in the planar direction of the first shield surface 32 and the second shield surface 34.

By placing a foam gasket in the overlapping region so that space is secured by the thickness of the foam gasket, and then stitching through the foam gasket, the foam gasket becomes compressed by the stitching and expands around the compressed area. That is, the foam gasket's restoring force causes it to expand outward, and the expanded foam gasket reduces any empty space of the needle holes formed by the stitching, thereby further improving shielding efficiency.

The foam gasket 40 may be formed by sequentially coating a copper plating layer and a non-oxidizing metal plating layer on the outer circumferential surface of a polymer-based non-conductive elastomer. Additionally, it may be formed as a foam gasket by laminating a conductive fabric or a conductive metal film onto one or both sides of a sheet using a polymer elastomer, then drilling holes of 0.1 mm to 3.0 mm in diameter in the sheet, and applying a conductive material to the perforated areas to form a conductive layer.

The thickness of such a foam gasket 40 may be from 5 mm to 30 mm, preferably from 10 mm to 30 mm. By satisfying a thickness of 5 mm to 30 mm, excellent workability and shielding efficiency may be obtained.

Specific examples of such a shield tent with excellent electromagnetic wave shielding effect are set forth below.

For the following tests, identical materials and fabrics were used for all surfaces, except for the door attachment method. Neodymium magnets, each having dimensions of 10 mm (width)×30 mm (length)×5 mm (thickness), were used. The first and second polymer plates were made of polycarbonate, each having a width of 90 mm and lengths of 200 mm and 100 mm, respectively, with a thickness of 2 mm. To prevent bending, two reinforcement strips (stiffeners), each having a width of 10 mm and a thickness of 2 mm, were used.

When the first polymer plate had a length of 200 mm, two magnets were attached to the central portion of the first polymer plate, spaced apart from each other. When the second polymer plate had a length of 100 mm, a single magnet was attached to the central portion of the second polymer plate.

When the same type of magnets were used on the opposite polymer plate, magnets with reversed polarity were used. When metal was used, a galvanized steel sheet (thickness: 0.25 mm) was attached by tape having a width of 30 mm.

As a result, specimens for Example 1 in Tables 3 and 4 were produced.

The button as a coupling member of Example 2 and the shape of the first polymer plate and second polymer plate are illustrated in FIGS. 6 and 7. Accordingly, specimens for Example 2 in Table 5 were produced.

### <Measurement Method>

FIG. 10 illustrates a shielding efficiency measurement method according to Example 1 or Example 2.

As shown in FIG. 10, when a frequency to be measured is transmitted from a transmitter, the electric field intensity between Tx1 and Rx1 is measured. This measurement is defined as the Ref Level.

Next, the transmitting antenna is placed inside the shield tent, the door is closed, and the electric field intensity between Tx2 and Rx2 is measured under the same conditions. This measurement is defined as the Received Level.

The difference between the external electric field and internal electric field is defined as the shielding performance.

TABLE 1
Measurement after fastening a single
conventional double-zipper type door

Result

| | | Received | |
|---|---|---|---|
| | Ref Level | Level | Shielding |
| Frequency | (External) | (Internal) | Effect |

| | | | | |
|---|---|---|---|---|
| 900 | MHz | −13 dB | −44 dB | 31 dB |
| 2.4 | GHz | −15 dB | −65 dB | 50 dB |
| 5.8 | GHz | −40 dB | −76 dB | 36 dB |

TABLE 2
Measurement after fastening two conventional
double-zipper type doors

Result

| | | Received | |
|---|---|---|---|
| | Ref Level | Level | Shielding |
| Frequency | (External) | (Internal) | Effect |

| | | | | |
|---|---|---|---|---|
| 900 | MHz | −13 dB | −80 dB | 67 dB |
| 2.4 | GHz | −15 dB | −78 dB | 63 dB |
| 5.8 | GHz | −40 dB | −85 dB | 45 dB |

TABLE 3
First polymer plate with magnet +
second polymer plate with metal (Example 1)

Result

| | | Received | |
|---|---|---|---|
| | Ref Level | Level | Shielding |
| Frequency | (External) | (Internal) | Effect |

| | | | | |
|---|---|---|---|---|
| 900 | MHz | −14 dB | −83 dB | 69 dB |
| 2.4 | GHz | −14 dB | −82 dB | 68 dB |
| 5.8 | GHz | −43 dB | −92 dB | 49 dB |

TABLE 4
First polymer plate with magnet +
second polymer plate with magnet (Example 1)

Result

| | | Received | |
|---|---|---|---|
| | Ref Level | Level | Shielding |
| Frequency | (External) | (Internal) | Effect |

| | | | | |
|---|---|---|---|---|
| 900 | MHz | −14 dB | −92 dB | 80 dB |
| 2.4 | GHz | −14 dB | −92 dB | 80 dB |
| 5.8 | GHz | −43 dB | −93 dB | 50 dB |

The shielding effects in Tables 3 and 4 corresponding to Example 1 of the present invention showed higher values than those measured after fastening two conventional double-zipper type doors in Tables 1 and 2.

At 5.8 GHz, due to measurement equipment limitations and the high Ref Level value, it was not possible to measure shielding rates higher than those indicated.

Thus, it was confirmed that the shield tent of the present invention provides an excellent electromagnetic wave shielding effect, since it allows easy opening and closing, has a large shielding area, and exhibits excellent magnetic attraction between polymer plates.

TABLE 5
First polymer plate with magnet + second
polymer plate with metal (FIGS. 6 and 8)

Result

| | | Received | |
|---|---|---|---|
| | Ref Level | Level | Shielding |
| Frequency | (External) | (Internal) | Effect |

| | | | | |
|---|---|---|---|---|
| 900 | MHz | −13 dB | −80 dB | 67 dB |
| 2.4 | GHz | −11 dB | −79 dB | 68 dB |
| 5.8 | GHz | −40 dB | −92 dB | 52 dB |

The shielding effect shown in Table 5, corresponding to Example 2 of the present invention, achieved high values of 50 dB or more.

At 5.8 GHz, due to measurement equipment limitations and the high Ref Level value, it was not possible to measure shielding rates higher than those indicated.

Therefore, it was confirmed that the shield tent of the present invention provides an excellent electromagnetic wave shielding effect by continuously arranging curved polymer plates, thus minimizing the gap between the plates and attenuating electromagnetic waves.

Although the present invention has been described with reference to exemplary embodiments and the accompanying drawings, it should be understood that the invention is not limited to the embodiments disclosed herein. Various modifications may be made by those skilled in the art within the scope of the technical concept of the present invention. Moreover, even though specific operational effects based on the structure of the present invention were not explicitly described when explaining the embodiments, it is understood that any predictable effects resulting from such configurations should also be recognized.

### DESCRIPTION OF REFERENCE NUMERALS AND SYMBOLS

10: shield surface
12: opening
14: magnet
16: metal
18: first polymer plate
20: door
22: second polymer plate
24: pocket
32: first shield surface
34: second shield surface
36: stitch line
40: foam gasket

What is claimed is:

1. A shield tent comprising:
a shield surface including an opening; and
a door, disposed on an outer surface of the shield surface, configured to cover the opening;
wherein a first polymer plate, to which a magnet or a metal is attached, is disposed at an edge of the opening on an inner surface of the shield surface, and a second polymer plate, to which a magnet or a metal is attached, is disposed at an edge of the door.

2. A shield tent comprising:
a shield surface including an opening; and
a door, disposed on an outer surface of the shield surface, configured to cover the opening;
wherein a plurality of first polymer plates are continuously arranged at an edge of the opening on an inner surface of the shield surface;
a plurality of second polymer plates are continuously arranged at an edge of the door;
each of the first polymer plate includes a magnet or a metal;
each of the second polymer plate includes a magnet or a metal;
a groove and a protrusion having the same shape as the groove face each other on a side where one first polymer plate and another adjacent first polymer plate contact each other; and
a groove and a protrusion having the same shape as the groove face each other on a side where one second polymer plate and another adjacent second polymer plate contact each other.

3. The shield tent according to claim 2,
wherein each of the groove and protrusion comprises a first surface and a second surface perpendicular to the first surface, or comprises a curved surface.

4. The shield tent according to claim 1,
wherein when the door is coupled to the edge of the opening on the outer surface of the shield surface, the rear surface of the first polymer plate faces the rear surface of the second polymer plate, and
a cushioning sheet is disposed on at least one of the rear surface of the first polymer plate and the rear surface of the second polymer plate.

5. The shield tent according to claim 2,
wherein when the door is coupled to the edge of the opening on the outer surface of the shield surface, the rear surface of the first polymer plate faces the rear surface of the second polymer plate, and
a cushioning sheet is disposed on at least one of the rear surface of the first polymer plate and the rear surface of the second polymer plate.

6. The shield tent according to claim 4,
wherein the cushioning sheet comprises at least one resin selected from the group consisting of polyurethane-based resins, acrylic-based resins, ethylene propylene diene monomer (EPDM)-based resins, melamine-based resins, silicone-based resins, and fluorine-based resins.

7. The shield tent according to claim 5,
wherein the cushioning sheet comprises at least one resin selected from the group consisting of polyurethane-based resins, acrylic-based resins, ethylene propylene diene monomer (EPDM)-based resins, melamine-based resins, silicone-based resins, and fluorine-based resins.

8. The shield tent according to claim 1,
wherein the magnet comprises neodymium, and
the metal comprises at least one selected from the group consisting of cobalt, iron, and nickel.

9. The shield tent according to claim 2,
wherein the magnet comprises neodymium, and
the metal comprises at least one selected from the group consisting of cobalt, iron, and nickel.

10. The shield tent according to claim 1,
wherein each of the first polymer plate and the second polymer plate is accommodated in a pocket, and each pocket is fixed, in a sealed condition, to the edge of the opening on the inner surface of the shield surface and to the edge of the door.

11. The shield tent according to claim 2,
wherein each of the first polymer plate and the second polymer plate is accommodated in a pocket, and each pocket is fixed, in a sealed condition, to the edge of the opening on the inner surface of the shield surface and to the edge of the door.

12. The shield tent according to claim 2,
wherein a coupling member is located on an upper portion of the first polymer plate,
a coupling member is located on a lower portion of the second polymer plate,
the coupling member of the first polymer plate is maintained without contact with the second polymer plate, and
the coupling member of the second polymer plate is maintained without contact with the first polymer plate.

13. The shield tent according to claim 1,
wherein a thickness of each of the first polymer plate and the second polymer plate ranges from 1 mm to 5 mm.

14. The shield tent according to claim 2,
wherein a thickness of each of the first polymer plate and the second polymer plate ranges from 1 mm to 5 mm.

15. The shield tent according to claim 1,
wherein the shield surface comprises a stitch line where a first shield surface and a second shield surface overlap,
a foam gasket is disposed in an overlapping region on an inner surface of the shield surface such that the first shield surface and the second shield surface overlap on three continuous faces of the foam gasket, and
the stitch line of the overlapping first shield surface, second shield surface, and foam gasket lies in a planar direction of the shield surface.

16. The shield tent according to claim 2,
wherein the shield surface comprises a stitch line where a first shield surface and a second shield surface overlap,
a foam gasket is disposed in an overlapping region on an inner surface of the shield surface such that the first shield surface and the second shield surface overlap on three continuous faces of the foam gasket, and
the stitch line of the overlapping first shield surface, second shield surface, and foam gasket lies in a planar direction of the shield surface.
